(19) United States
(12) Patent Application Publication
(10) Pub. No.: US 2025/0146952 A1
(43) Pub. Date: May 8, 2025

(54) SUBSTRATE STATE MEASUREMENT DEVICE, PLATING APPARATUS, AND SUBSTRATE STATE MEASUREMENT METHOD

(71) Applicant: EBARA CORPORATION, Tokyo (JP)

(72) Inventors: Masashi SHIMOYAMA, Tokyo (JP); Yasuyuki MASUDA, Tokyo (JP); Ryosuke HIWATASHI, Tokyo (JP)

(21) Appl. No.: 18/557,557

(22) PCT Filed: Aug. 26, 2022
(86) PCT No.: PCT/JP2022/032188

§ 371 Date: Jan. 17, 2025

(51) Int. Cl. G01N 21/95; C25D 7/12; C25D 17/00; C25D 21/12

(52) U.S. Cl. CPC G01N 21/9501; C25D 7/123; C25D 17/001; C25D 21/12

(57) ABSTRACT

A state of a substrate as a plating target is measured. A substrate state measurement device includes: a stage configured to support a substrate such that the stage rotates the substrate, the substrate including a seed layer and a resist layer formed on the seed layer; at least one white confocal sensor adapted to measure a plate surface of the substrate supported by the stage; and a state measurement module adapted to measure a state of a power supply member contact area on the basis of detection performed by the white confocal sensor on the power supply member contact area, the power supply member contact area being an area on the substrate which comes into contact with a power supply member.

### TECHNICAL FIELD

The present application relates to a substrate state measurement device, a plating apparatus, and a substrate state measurement method.

### BACKGROUND ART

As an example of plating apparatuses, a cup-type electrolytic plating apparatus is known (see PTL 1, for example). The cup-type electrolytic plating apparatus is adapted such that a substrate (for example, a semiconductor wafer) held by a substrate holder with a plated surface facing downward is immersed into a plating solution, a voltage is applied between the substrate and an anode, and a conductive film is thereby precipitated on the surface of the substrate.

In order to plate the substrate by the electrolytic plating apparatus, a resist layer having a resist pattern is formed on the substrate, such as a semiconductor wafer, with a seed layer formed thereon in advance. Subsequently, the substrate with the resist layer formed thereon is irradiated with ultraviolet light or the like, residues of the resist on the surface of the substrate are removed (ashing process), and a hydrophilization process (descum process) of the resist surface is performed.

Also, according to a typical plating apparatus, a user sets parameters such as a plating current value and a plating time as a plating process recipe in advance on the basis of a target plating film thickness and an actual plating area of a substrate on which a plating process is to be performed, and the plating process is performed on the basis of the set process recipe (see PTL 2, for example). Additionally, the plating process is performed on the basis of the same process recipe on a plurality of wafers on the same carrier.

### CITATION LIST

### Patent Literature

PTL 1: Japanese Patent Laid-Open No. 2008-19496
PTL 2: Japanese Patent Laid-Open No. 2002-105695

### SUMMARY OF INVENTION

### Technical Problem

As described above, a seed layer and a resist layer are formed in a substrate prior to a plating process. However, uniformity of a thickness of a plating film formed on the substrate may be degraded due to states of the seed layer, the resist layer, and the like formed in the substrate. In one example, power supply is performed with the substrate coming into contact with a power supply member (contact) of a substrate holder, and if there are resist residues or the like that may be obstacles of power distribution in a substrate area that comes into contact with the power supply member, an appropriate plating process cannot be performed. Also, in one example, a so-called dry contact scheme in which the surroundings of contact between the power supply member and the substrate are insulated from a plating solution by a sealing member may be employed for an electrolytic plating apparatus. In such a case, if there is irregularity or a foreign matter in the contact area on the substrate with the sealing member, the plating solution may invade the contact part between the power supply member and the substrate, and an appropriate plating process cannot be performed. Furthermore, a desired resist pattern is formed on the substrate in accordance with a plating pattern that is desired to be formed on the substrate. However, if the resist pattern formed on the substrate, particularly, an aperture ratio of the substrate differs, a density of a current flowing between the substrate and the anode changes, which may affect uniformity of the plating film thickness or a time required for the plating process. As described above, if the state of the substrate as a plating target is known, it is possible to suitably perform the plating process by avoiding the plating process on the substrate where abnormality has occurred or by performing the plating process in accordance with the state of the substrate.

In view of the above circumstances, one of objects of the present application is to measure a state of a substrate as a plating target.

### Solution to Problem

According to an embodiment, proposed is a substrate state measurement device, the substrate state measurement device includes: a stage configured to support a substrate such that the stage is able to rotate the substrate, the substrate including a seed layer and a resist layer formed on the seed layer; and at least one white confocal sensor adapted to measure a plate surface of the substrate supported by the stage, and a state of a power supply member contact area is measured on the basis of detection performed by the white confocal sensor on the power supply member contact area, the power supply member contact area being an area on the substrate which comes into contact with a power supply member.

According to an embodiment, proposed is a substrate state measurement device, the substrate state measurement device includes: a stage configured to support a substrate such that the stage is able to rotate the substrate, the substrate including a seed layer and a resist layer formed on the seed layer; and at least one white confocal sensor adapted to measure a plate surface of the substrate supported by the stage, and a state of a sealing member contact area is measured on the basis of detection performed by the white confocal sensor on the sealing member contact area, the sealing member contact area being an area on the substrate which comes into contact with a sealing member.

According to an embodiment, proposed is a substrate state measurement device, the substrate state measurement device includes: a stage configured to support a substrate such that the stage is able to rotate the substrate, the substrate including a seed layer and a resist layer formed on the seed layer; and at least one white confocal sensor adapted to measure a plate surface of the substrate supported by the stage, and a state of a plated area is measured on the basis of detection performed by the white confocal sensor on the plated area on the substrate.

According to another embodiment, proposed is a substrate state measurement method, and the substrate state measurement method includes: arranging a substrate on a stage, the substrate including a seed layer and a resist layer formed on the seed layer; detecting a power supply member contact area by a white confocal sensor while rotating the substrate arranged on the stage, the power supply member contact area being an area on the substrate which comes into contact with a power supply member; and measuring a state of the power supply member contact area on the basis of detection performed by the white confocal sensor.

According to another embodiment, proposed is a substrate state measurement method, and the substrate state measurement method includes: arranging a substrate on a stage, the substrate including a seed layer and a resist layer formed on the seed layer; detecting a sealing member contact area by a white confocal sensor while rotating the substrate arranged on the stage, the sealing member contact area being an area on the substrate which comes into contact with a sealing member; and measuring a state of the sealing member contact area on the basis of detection performed by the white confocal sensor.

According to another embodiment, proposed is a substrate state measurement method, and the substrate state measurement method includes: arranging a substrate on a stage, the substrate including a seed layer and a resist layer formed on the seed layer; detecting a plated area on the substrate by a white confocal sensor while rotating the substrate arranged on the stage; and measuring a state of the plated area on the basis of detection performed by the white confocal sensor.

### BRIEF DESCRIPTION OF DRAWINGS

FIG. 1 is a perspective view illustrating an overall configuration of a plating apparatus of an embodiment.

FIG. 2 is a plan view illustrating the overall configuration of the plating apparatus of the embodiment.

FIG. 3 is a longitudinal sectional view schematically illustrating a configuration of a plating module of the embodiment.

FIG. 4 is a diagram schematically illustrating a plate surface of a substrate according to the embodiment.

FIG. 5 is a longitudinal sectional view schematically illustrating a configuration of a substrate state measurement module according to the embodiment.

FIG. 6 is a schematic diagram for explaining state measurement performed by the substrate state measurement module according to the embodiment.

FIG. 7 is a diagram illustrating an example of a white confocal sensor and a substrate section according to the embodiment.

FIG. 8 is a diagram illustrating an example of a signal detection value obtained by the white confocal sensor.

FIG. 9 is a flowchart illustrating an example of a substrate state measurement method performed by the substrate state measurement module.

FIG. 10 is a schematic functional block diagram of the substrate state measurement module according to the embodiment.

FIG. 11 is a longitudinal sectional view schematically illustrating a configuration of a substrate state measurement module according to a modification.

### DESCRIPTION OF EMBODIMENTS

Hereinafter, embodiments of the present invention will be described with reference to the drawings. In the drawings described below, the same or corresponding components are denoted with the same reference signs and will not be described in duplicate.

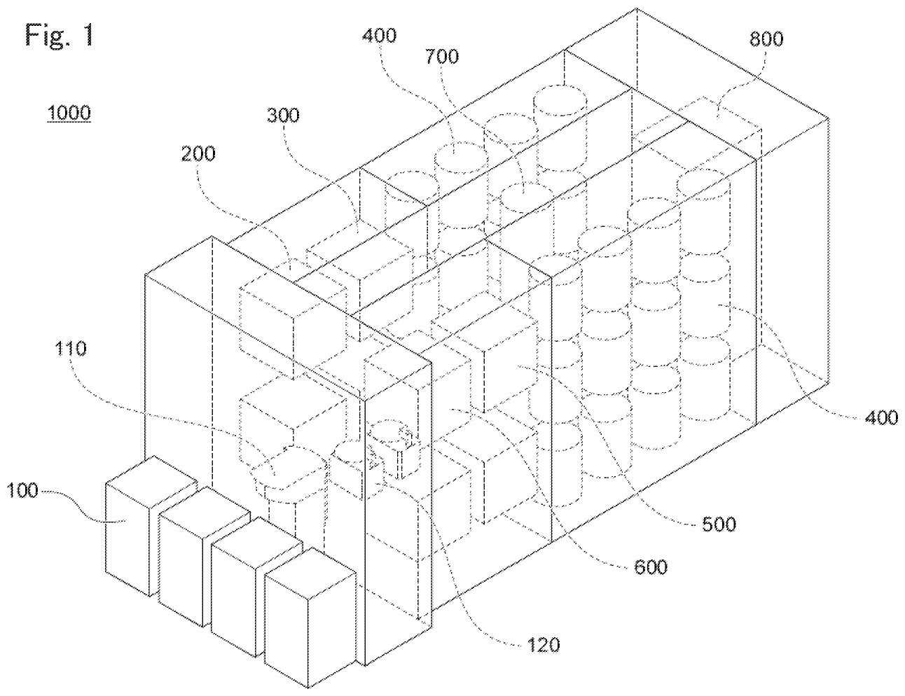

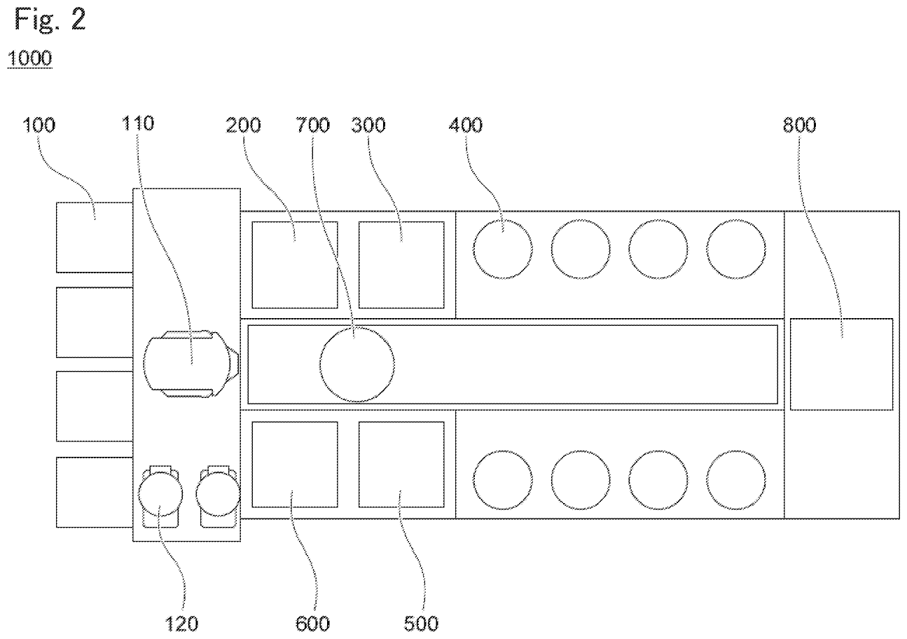

FIG. 1 is a perspective view illustrating the overall configuration of a plating apparatus 1000 of an embodiment of the present invention. FIG. 2 is a plan view illustrating the overall configuration of the plating apparatus 1000. As illustrated in FIGS. 1 and 2, the plating apparatus 1000 includes load ports 100, a transfer robot 110, aligners 120, pre-wet modules 200, pre-soak modules 300, plating modules 400, cleaning modules 500, spin rinse dryers 600, a transfer device 700, and a control module 800.

Each load port 100 is a module for loading a substrate that is a target object to be plated housed in a cassette, such as a FOUP (not illustrated), to the plating apparatus 1000 and unloading the substrate from the plating apparatus 1000 to the cassette. While four load ports 100 are arranged in the horizontal direction in this embodiment, the number of load ports 100 and arrangement of the load ports are arbitrary. The transfer robot 110 is a robot for transferring the substrate and is configured to grip or release the substrate between the load port 100, each aligner 120, and the transfer device 700. The transfer robot 110 and the transfer device 700 can perform delivery and receipt of the substrate via a temporary placement table (not illustrated) to grip or release the substrate between the transfer robot 110 and the transfer device 700.

The aligner 120 is a module for adjusting a position of an orientation flat, a notch, or the like of the substrate in a predetermined direction. While two aligners 120 are arranged in a horizontal direction in this embodiment, the number of aligners 120 and arrangement of the aligners are arbitrary. The pre-wet module 200 wets a surface to be plated of the substrate before a plating process with a process liquid (pre-wet liquid), such as pure water or deaerated water, to replace air inside a pattern formed on the surface of the substrate with the process liquid. The pre-wet module 200 is configured to perform a pre-wet process to facilitate supplying a plating solution to the inside of the pattern by replacing the process liquid inside the pattern with the plating solution during plating. While two pre-wet modules 200 are arranged in a vertical direction in this embodiment, the number of pre-wet modules 200 and arrangement of the pre-wet modules are arbitrary.

For example, the pre-soak module 300 is configured to remove an oxidized film having a large electrical resistance present on the surface of a seed layer formed on the surface to be plated of the substrate before the plating process by etching with a process liquid, such as sulfuric acid and hydrochloric acid, and perform a pre-soak process of cleaning or activating the surface of a plating base layer. While two pre-soak modules 300 are arranged in the vertical direction in this embodiment, the number of pre-soak modules 300 and arrangement of the pre-soak modules are arbitrary. The plating module 400 performs the plating process on the substrate. There are two sets of 12 plating modules 400 arranged by three in the vertical direction and by four in the horizontal direction, and 24 plating modules 400 in total are provided in this embodiment, but the number of plating modules 400 and arrangement of the plating modules are arbitrary.

Each cleaning module 500 is configured to perform a cleaning process on the substrate to remove the plating solution or the like left on the substrate after the plating process. While two cleaning modules 500 are arranged in the vertical direction in this embodiment, the number of cleaning modules 500 and arrangement of the cleaning modules are arbitrary. Each spin rinse dryer 600 is a module for rotating the substrate after the cleaning process at high speed and drying the substrate. While two spin rinse dryers are arranged in the vertical direction in this embodiment, the number of spin rinse dryers and arrangement of the spin rinse dryers are arbitrary. The transfer device 700 is a device for transferring the substrate between the plurality of modules inside the plating apparatus 1000. The control module 800 is configured to control the plurality of modules in the plating apparatus 1000 and can be configured of, for example, a general computer including input/output interfaces with an operator or a dedicated computer.

An example of a sequence of plating processes by the plating apparatus 1000 will be described. First, the substrate housed in the cassette is loaded on the load port 100. Subsequently, the transfer robot 110 grips the substrate from the cassette at the load port 100 and transfers the substrate to the aligners 120. Each aligner 120 adjusts the position of the orientation flat, the notch, or the like of the substrate in the predetermined direction. The transfer robot 110 grips or releases the substrate whose direction is adjusted with the aligners 120 to the transfer device 700.

The transfer device 700 transfers the substrate received from the transfer robot 110 to the pre-wet module 200. The pre-wet module 200 performs the pre-wet process on the substrate. The transfer device 700 transfers the substrate on which the pre-wet process has been performed to the pre-soak module 300. The pre-soak module 300 performs the pre-soak process on the substrate. The transfer device 700 transfers the substrate on which the pre-soak process has been performed to the plating module 400. The plating module 400 performs the plating process on the substrate.

The transfer device 700 transfers the substrate on which the plating process has been performed to the cleaning module 500. The cleaning module 500 performs the cleaning process on the substrate. The transfer device 700 transfers the substrate on which the cleaning process has been performed to the spin rinse dryer 600. The spin rinse dryer 600 performs a drying process on the substrate. The transfer device 700 grips or releases the substrate on which the drying process has been performed to the transfer robot 110. The transfer robot 110 transfers the substrate received from the transfer device 700 to the cassette at the load port 100. Finally, the cassette housing the substrate is unloaded from the load port 100.

### <Configuration of Plating Module>

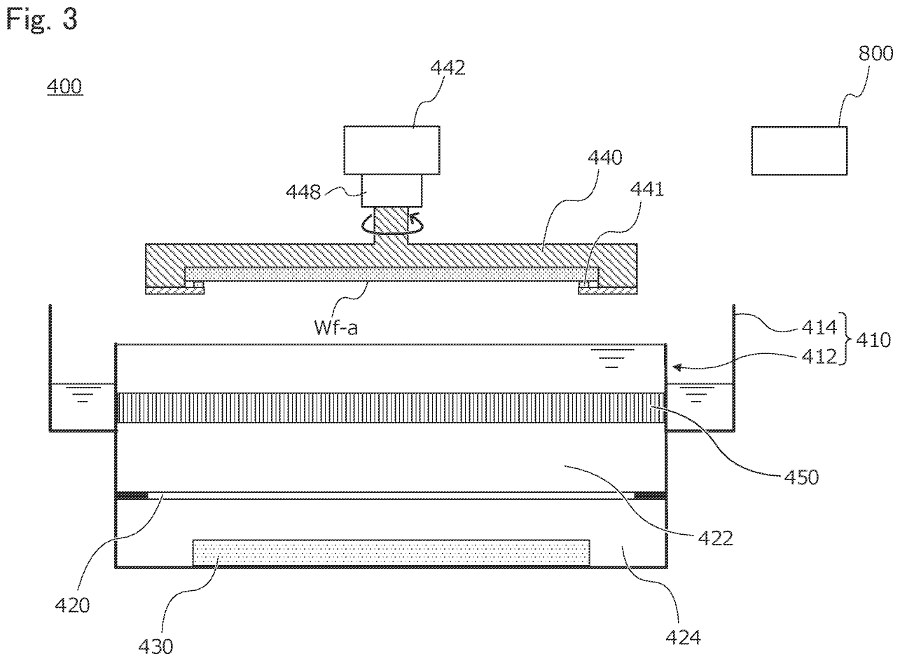

Next, a configuration of the plating module 400 will be described. Since 24 plating modules 400 in the present embodiment include the same configuration, one plating module 400 alone will be described. FIG. 3 is a longitudinal sectional view schematically illustrating the configuration of the plating module 400 of the present embodiment. As illustrated in FIG. 3, the plating module 400 includes a plating tank 410 for storing a plating solution. The plating tank 410 includes a cylindrical inner tank 412 having an opened upper surface, and an outer tank 414 disposed around the inner tank 412 for receiving the plating solution overflown from an upper edge of the inner tank 412.

The plating module 400 includes a membrane 420 that splits the inside of the inner tank 412 in the up-down direction. The inside of the inner tank 412 is sectioned into a cathode area 422 and an anode area 424 by the membrane 420. Each of the cathode area 422 and the anode area 424 is filled with a plating solution. An anode 430 is provided on a bottom surface of the inner tank 412 in the anode area 424. A resistor 450 facing the membrane 420 is arranged in the cathode area 422. The resistor 450 is a member for uniformizing a plating process on a plated surface Wf-a of a substrate Wf. Note that although the example in which the membrane 420 is provided has been described in the present embodiment, the membrane 420 may not be provided.

Also, the plating module 400 includes a substrate holder 440 for holding the substrate Wf in a state where the plated surface Wf-a faces downward. The substrate holder 440 grips an edge portion of the substrate Wf in a state where a partial area (plated area) of the plated surface Wf-a is exposed. The substrate holder 440 includes a power supply contact point that comes into contact with the substrate Wf and supplies power from a power source, which is not illustrated, to the substrate Wf. In the present embodiment, a so-called dry contact scheme in which a contact part between the power supply contact point of the substrate holder 440 and the substrate Wf is shielded from the plating solution or another solution is employed. The substrate holder 440 has a sealing member 441 that seals a power supply contact point contact area (contact area CA) on the substrate Wf to prevent the plating solution from acting on the contact part between the power supply contact point and the substrate Wf.

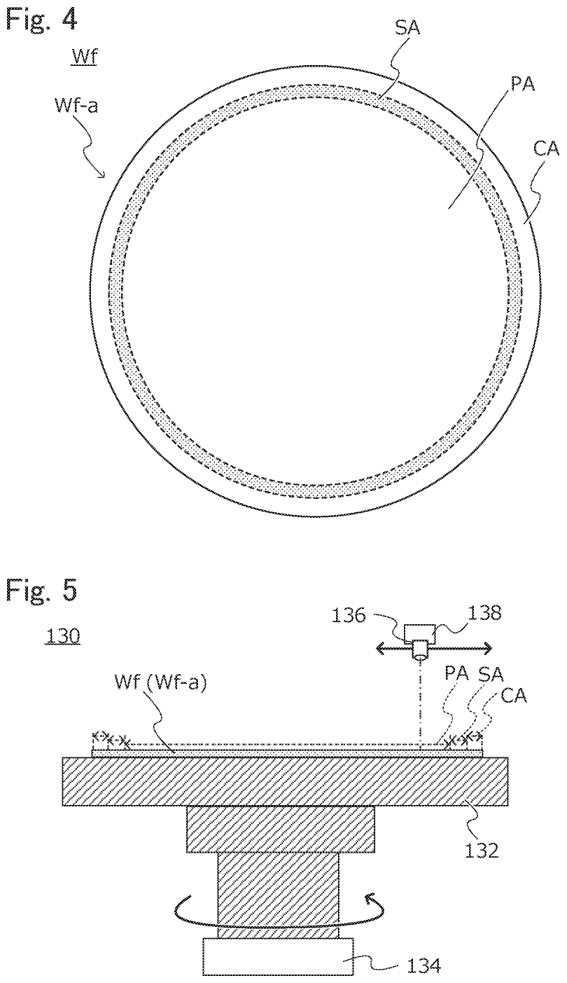

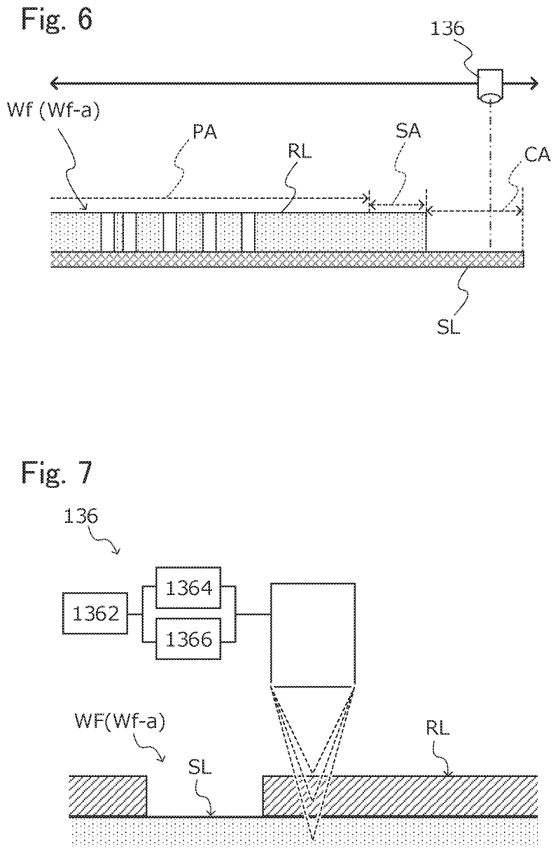

FIG. 4 is a diagram schematically illustrating a plate surface (plated surface Wf-a) of the substrate Wf according to the present embodiment. In the present embodiment, the substrate Wf is a circular substrate. As illustrated in the drawing, a circular plated area PA is formed on the inner peripheral side, and an annular contact area CA to establish contact with the power supply contact point of the substrate holder 440 is formed on the outer peripheral side of the plated area PA, on the substrate Wf. Also, an annular sealing member contact area (sealed area) SA with which the sealing member 441 of the substrate holder 440 comes into contact is provided between the plated area PA and the contact area CA. Note that for easiness of understanding, the sealed area SA is hatched in FIG. 4. In the present embodiment, a seed layer SL is formed in the contact area CA with the seed layer SL not covered with a resist layer RL such that the seed layer SL can come into contact with and establish electric continuity with the power supply contact point of the substrate holder 440 (see FIG. 6). Also, the resist layer RL is uniformly formed in the sealed area SA such that the resist layer RL is in contact with the sealing member 441 of the substrate holder 440 and seals the plating solution (see FIG. 6). Additionally, the resist layer RL of a resist pattern having openings communicating with the seed layer SL is formed in the plating area PA such that a desired plating pattern is formed through a plating process (see FIG. 6).

Referring again to FIG. 3, the plating module 400 includes a lifting/lowering mechanism 442 for lifting/lowering the substrate holder 440. Also, the plating module 400 includes a rotation mechanism 448 that rotates the substrate holder 440 about a vertical axis in one embodiment. The lifting/lowering mechanism 442 and the rotation mechanism 448 can be realized by known mechanisms such as motors, for example. The plated area PA on the substrate Wf is exposed to the plating solution by immersing the substrate Wf in the plating solution in the cathode area 422 by using the lifting/lowering mechanism 442. Also, in an embodiment, the plating process is performed while the substrate holder 440 is rotated by using the rotation mechanism 448. The plating module 400 is configured to perform the plating process on the plated surface Wf-a (plated area PA) of the substrate Wf by applying a voltage between the anode 430 and the substrate Wf in this state.

Note that although the aforementioned plating module 400 is adapted to perform the plating process in the state where the plated surface Wf-a of the substrate Wf is caused to face downward, the present invention is not limited to such an example. In an example, the plating module 400 may perform the plating process in a state where the plated surface Wf-a is caused to face upward or a side.

### <Substrate State Measurement Module>

The plating apparatus 1000 includes a substrate state measurement module 130 for measuring a state of the substrate Wf prior to a plating process performed by the plating module 400. The substrate state measurement module 130 corresponds to an example of a substrate state measurement device. FIG. 5 is a longitudinal sectional view schematically illustrating a configuration of the substrate state measurement module 130 according to an embodiment, and FIG. 6 is a schematic diagram for explaining state measurement performed by the substrate state measurement module 130. The substrate state measurement module 130 is provided in the aligner 120 in an example. However, the substrate state measurement module 130 may be provided in any of the pre-wet module 200, the pre-soak module 300, or the transfer device 700. Also, the substrate state measurement module 130 may be provided as an independent module.

The substrate state measurement module 130 includes a stage 132 configured to support and rotate the substrate Wf. The rotation mechanism 134 that rotates the stage 132 can be realized by a known mechanism such as a motor, for example. Also, the substrate state measurement module 130 includes a white confocal sensor 136 for measuring a plate surface of the substrate Wf placed on the stage 132. In the example illustrated in FIG. 5, the white confocal sensor 136 is configured to be movable by the moving mechanism 138. It is thus possible to change the detection position of the white confocal sensor 136. Note that the moving mechanism 138 is preferably configured to move the white confocal sensor 136 along a radial direction of the substrate Wf though not limited thereto. In the present embodiment, the substrate state measurement module 130 includes one white confocal sensor 136 and can change the detection position of the white confocal sensor 136 to the contact area CA, the sealed area SA, and the plating area PA by the moving mechanism 138 as illustrated in FIG. 6.

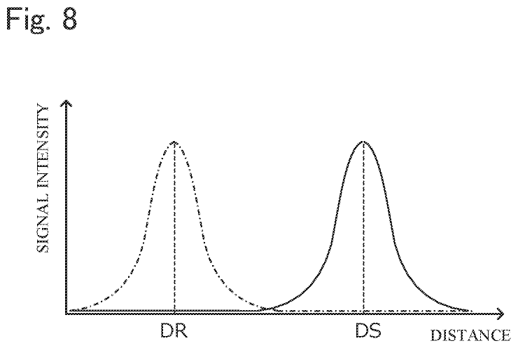

FIG. 7 is a diagram illustrating an example of the white confocal sensor and the substrate section according to the present embodiment, and FIG. 8 is a diagram illustrating an example of a signal detection value obtained by the white confocal sensor. The white confocal sensor 136 includes a light source 1364 that generates irradiation light having a plurality of wavelength components, a light receiving unit 1366 that receives reflected light from the substrate Wf, and a processing unit 1362 that measures a distance to an interface position where light is reflected on the basis of the wavelength components of the light received by the light receiving unit 1366.

The irradiation light is reflected by the surface of the seed layer SL when the area of the substrate Wf where the seed layer SL is exposed is irradiated. In this manner, a signal intensity indicating the distance (A1 in FIG. 5) to the seed layer SL as the distance to the substrate Wf calculated by the processing unit 1362 is exhibited to be high. On the other hand, the irradiation light is reflected mainly by the surface of the resist layer RL when the resist layer RL on the substrate Wf is irradiated with the irradiation light. In this manner, a signal intensity indicating the distance (A2 in FIG. 5) to the resist layer RL as the distance to the substrate Wf calculated by the processing unit 1362 is exhibited to be high. Additionally, in a case where the resist layer RL transmits a part of the irradiation light, a part of the irradiation light emitted to the resist layer RL is reflected by the surface of the resist layer RL, and another part of the irradiation light is transmitted through the resist layer RL and is reflected by the seed layer SL on the rear side of the resist layer RL. In this manner, each of signal intensities indicating the distance (A2) to the resist layer RL and the distance (A1) to the seed layer SL as the distance to the substrate Wf calculated by the processing unit 1362 is exhibited to be high.

The substrate state measurement module 130 measures the state of the substrate Wf on the basis of such detection performed by the white confocal sensor 136. The measurement of the state of the substrate Wf based on the detection performed by the white confocal sensor 136 is performed by the control module 800 in an example. In this case, the control module 800 constitutes a part of the substrate state measurement module 130. However, the present invention is not limited to such an example, and the substrate state measurement module 130 may include a configuration for measuring the state of the substrate Wf separately from the control module 800.

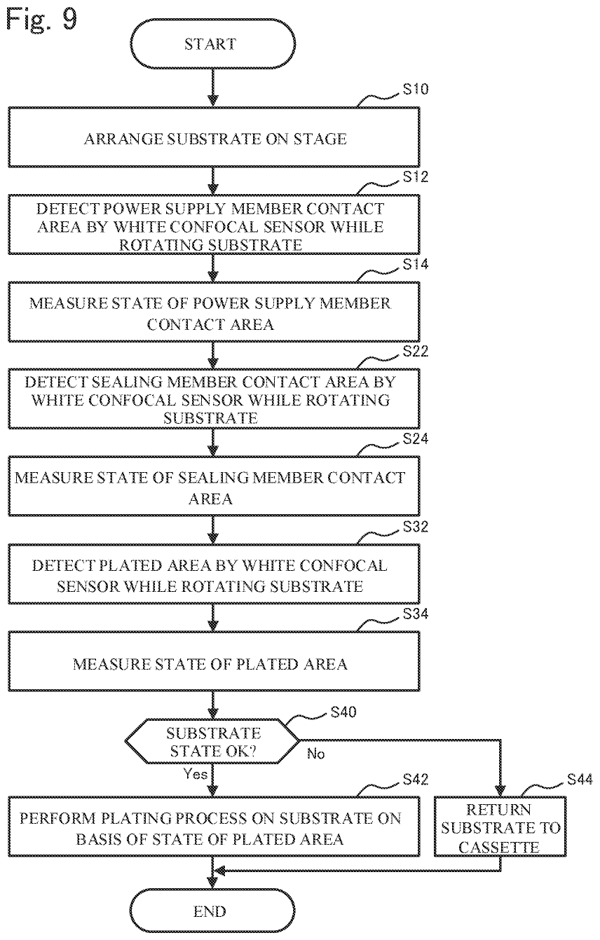

FIG. 9 is a flowchart illustrating an example of a substrate state measurement method performed by the substrate state measurement module 130. In the substrate state measurement method in the present embodiment, the substrate Wf is arranged on the stage 132 first (Step S10). The arrangement of the substrate Wf on the stage 132 is performed by the transfer robot 110, for example.

Subsequently, the power supply member contact area (contact area) CA is detected by the white confocal sensor 136 while the substrate Wf arranged on the stage 132 is rotated (Step S12), and the state of the contact area CA is measured on the basis of the detection (Step S14). The detection of the contact area CA performed by the white confocal sensor 136 is preferably performed with at least one rotation of the substrate Wf.

Here, the process in Step S12 is performed by rotating the substrate Wf at a low speed on the basis of a sampling cycle of the white confocal sensor 136 such that the distance between the white confocal sensor 136 and the substrate Wf can be measured over the entire contact area CA in a first example. As described above, the seed layer SL is formed in the contact area CA with the seed layer SL not covered by the resist layer RL, and in a preferable state of the substrate Wf, detection performed by the white confocal sensor 136 is constant over the entire contact area CA. Therefore, in the process in Step S14 in the first example, the substrate state measurement module 130 (control module 800) can determine that the contact area CA is normal in a case where the detection value is within a preset normal area over the entire contact area CA. Also, the substrate state measurement module 130 can determine that there is irregularity in the contact area CA, which is abnormality that a contact failure with the power supply contact point of the substrate holder 440 may cause in a case where a detection value outside the normal area is measured. Note that in the first example, the substrate state measurement module 130 preferably measures the state of the contact area CA in consideration of inclination of the substrate Wf and detection noise.

Also, the process in Step S12 is performed while the substrate Wf is rotated at such a high speed that signal intensities indicating a plurality of distances are exhibited to be high in the white confocal sensor 136 in a case where the contact area CA includes irregularity in a second example. In this case, a signal intensity indicating a single distance is detected by the white confocal sensor 136 over the entire contact area CA in the preferable state of the substrate Wf. Therefore, in the process in Step S14, the substrate state measurement module 130 (control module 800) can determine that the contact area CA is normal in a case where the single distance is detected over the entire contact area CA in the second example. Also, the substrate state measurement module 130 can determine that there is irregularity in the contact area CA, which is abnormality, in a case where signal intensities indicating a plurality of distances separated by a predetermined distance are measured. Note that the substrate state measurement module 130 preferably measures the state of the contact area CA in consideration of detection noise in the second example. Additionally, the second example is considered to be more excellent than the first example in terms of a small influence of the inclination of the substrate Wf on the detection.

Next, in the substrate state measurement method, the white confocal sensor 136 detects the sealing member contact area (sealed area) SA while the substrate Wf arranged on the stage 132 is rotated (Step S22), and the state of the sealed area SA is measured on the basis of the detection (Step S24). The detection of the sealed area SA performed by the white confocal sensor 136 is preferably performed with at least one rotation of the substrate Wf.

The process in Step S22 can be performed by rotating the substrate Wf at a low speed similarly to the process in the first example for Step S12 in the first example. As described above, the resist layer RL is uniformly formed in the sealed area SA, and the detection performed by the white confocal sensor 136 is uniform over the entire sealed area SA in the preferable state of the substrate Wf. Therefore, in the process in Step S24, the substrate state measurement module 130 (control module 800) can determine that the sealed area SA is normal in a case where the detection value is within a preset normal area over the entire sealed area SA in the first example. Also, the substrate state measurement module 130 can determine that there is irregularity in the sealed area SA, which is abnormality, in a case where a detection value outside the normal area is measured.

Also, the process in Step S22 can be performed while the substrate Wf is rotated at a high speed similarly to the process in the second example for Step S12 in the second example. In the second example, the substrate state measurement module 130 (control module 800) can determine that the sealed area SA is normal in a case where a specific number (one or two) distances are detected over the entire sealed area SA in the process in Step S24. Additionally, the substrate state measurement module 130 can determine that there is irregularity in the sealed area SA, which is abnormality, in a case where the detected distances change in an example.

Next, in the substrate state measurement method, the white confocal sensor 136 detects the plated area PA while the substrate Wf arranged on the stage 132 is rotated (Step S32), and the state of the plated area PA is measured on the basis of the detection (Step S34). The detection of the plated area PA performed by the white confocal sensor 136 is preferably performed with at least one rotation of the substrate Wf. Also, the detection of the plated area PA performed by the white confocal sensor 136 is preferably performed at a plurality of different positions in the radial direction of the substrate Wf. The detection of the plated area PA performed by the white confocal sensor 136 may be performed with movement of the white confocal sensor 136 achieved by the moving mechanism 138. Here, the detection on the plated area PA performed by the white confocal sensor 136 is preferably performed in the are of not more than 25% of the plated area PA.

The process in Step S32 is preferably performed while the substrate Wf is rotated at a low speed on the basis of the sampling cycle of the white confocal sensor 136 such that the distance between the white confocal sensor 136 and the substrate Wf can be measured over the entire detection area. As described above, the resist layer RL where the resist pattern is present is formed in the plated area PA, and the detection performed by the white confocal sensor 136 changes in accordance with the resist pattern. In the process in Step S34, the substrate state measurement module 130 (control module 800) preferably measures the aperture ratio of the resist layer RL on the basis of the detection performed by the white confocal sensor 136 in an example. Note that the substrate state measurement module 130 may measure normality/abnormality of the plated area PA as a state of the substrate Wf on the basis of the detection on the plated area PA performed by the white confocal sensor 136. For example, the substrate state measurement module 130 may determine that the plated area PA is abnormal in a case where the resist pattern in the plated area PA is abnormal or in a case where there is abnormality in the resist layer RL in the plated area PA.

Once the state of the substrate Wf is measured on the basis of the detection performed by the white confocal sensor 136, the substrate state measurement module 130 (control module 800) determines whether the state of the substrate Wf is normal (Step S40). In an example, the substrate state measurement module 130 determines that the state of the substrate Wf is normal when it is determined to be possible to perform the plating process on the substrate Wf normally, on the basis of the state of the contact area CA or the sealed area SA. On the other hand, the substrate state measurement module 130 determines that the state of the substrate Wf is abnormal when it is determined that the substrate Wf is in a state not suitable for holding achieved by the substrate holder 440, on the basis of the state of the contact area CA or the sealed area SA. Additionally, the substrate state measurement module 130 may determine that the state of the substrate Wf is abnormal on the basis of the state of the plated area PA.

When the state of the substrate Wf is determined to be normal (S40: Yes), the plating process is performed on the substrate Wf on the basis of the state of the plated area PA (Step S42), and the flowchart illustrated in FIG. 9 is ended. In the plating process, a voltage to be applied to the substrate Wf may be determined on the basis of the aperture ratio of the plated area PA, for example. On the other hand, when the state of the substrate Wf is determined to be abnormal (S40: No), the plating process is not performed, the substrate Wf is returned to a cassette such as an FOUP, which is not illustrated (Step S44), and the flowchart illustrated in FIG. 9 is ended. In this case, the user may be notified of the abnormality of the substrate Wf by using a buzzer, a monitor, or the like, which is not illustrated. According to such a method, it is possible to perform the plating process on the basis of the state of the substrate Wf. Also, it is possible to end the process on the substrate Wf when the substrate Wf is in a state where it is not possible to perform the plating process thereon, and thereby to improve process efficiency.

Note that in the substrate state measurement method illustrated in FIG. 9, the white confocal sensor 136 detects the contact area CA, the sealed area SA, and the plated area PA in this order. However, the order of the detection performed by the white confocal sensor 136 is arbitrary. Also, detection of at least one of the contact area CA, the sealed area SA, and the plated area PA may not be performed. In a case where the substrate holder 440 does not have the sealing member 441, for example, there is no sealed area SA in the substrate Wf, and thus the processes in Steps S22 and S24 may not be performed. Also, in the substrate state measurement method illustrated in FIG. 9, whether the state of the substrate Wf is normal is determined after the state of the plated area PA is measured. However, whether the state of the substrate Wf is normal may be determined first on the basis of the measurement of the state of the contact area CA or the sealed area SA, and in a case where the state of the substrate Wf is normal, the state of the plated area PA may be measured, and the plating process may then be performed on the substrate Wf.

### <State Measurement of Substrate Using Machine Learning>

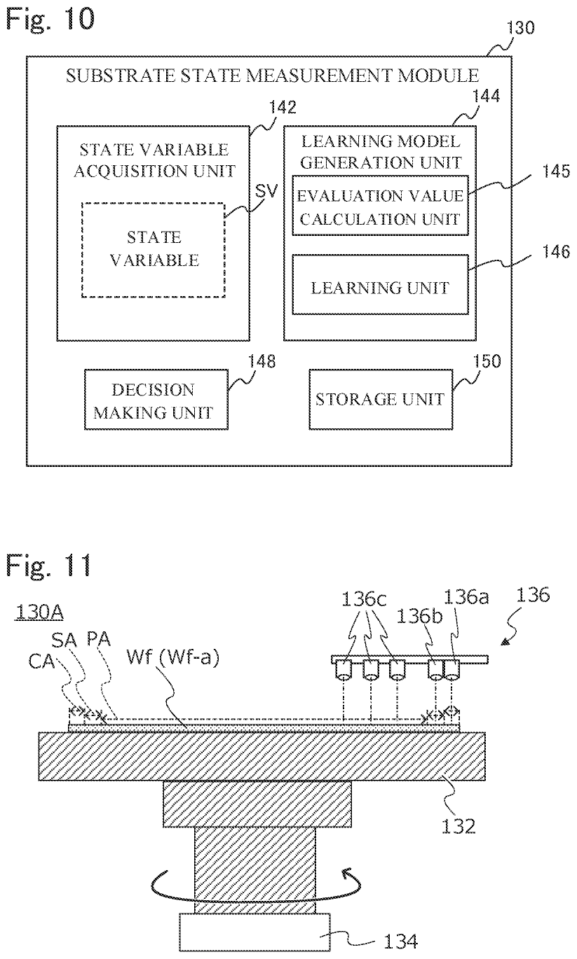

State (the state of the contact area CA, the state of the sealed area SA, the state of the plated area PA (the aperture ratio of the plated area)) measurement of the substrate Wf performed by the substrate state measurement module 130 may be performed by using a learning model constructed by machine learning. FIG. 10 is a schematic functional block diagram of the substrate state measurement module 130 according to the present embodiment. Note that the functional block illustrated in FIG. 10 may be realized by the control module 800 as a part of the substrate state measurement module 130 (substrate state measurement device). The substrate state measurement module 130 includes a state variable acquisition unit 142 that acquires a state variable SV, a learning model generation unit 144 that learns and generates a learning model to be stored in the storage unit 150 on the basis of the acquired state variable SV, and a decision making unit 148 that measures (make a decision regarding) the state of the substrate Wf on the basis of the acquired state variable SV and the learning model. Note that the decision making unit 148 may create image information indicating the state of the surface of the substrate Wf as a state of the substrate Wf on the basis of the state variable SV.

The state variable acquisition unit 142 acquires the state variable SV every predetermined time (several msec or several tens of msec, for example). In an example, the predetermined time can be a time that is the same as or corresponds to the learning cycle of the learning model generation unit 144. Note that in the present embodiment, an input from the white confocal sensor 136 corresponds to acquisition of the state variable SV performed by the state variable acquisition unit 142. The state variable SV may include information such as detection position information of the white confocal sensor 136 or a rotation speed of the substrate Wf. Also, the state variable SV may include information input to the plating apparatus 1000 by the user in advance. In an example, the state variable SV may include information such as a material of the substrate Wf.

The learning model generation unit 144 learns the learning model (the state of the substrate with respect to the state variable SV) in accordance with an arbitrary learning algorithm that is collectively called as machine learning. The learning model generation unit 144 repeatedly executes the learning based on the state variable SV acquired by the state variable acquisition unit 142. The learning model generation unit 144 acquires a plurality of state variables SV, identifies features of the state variables SV, and interprets correspondence. Also, the learning model generation unit 144 interprets the correspondence of the state variable SV acquired next when the substrate state is measured for the current state variable SV. Then, the learning model generation unit 144 optimizes estimation of the state of the substrate Wf with respect to the acquires state variable SV by repeating the learning.

In an example, the learning model generation unit 144 is constructed by a supervised learning. The supervised learning may be performed at a location where the plating apparatus 1000 is installed or may be performed at a manufacturing place or a dedicated learning place. The learning model generation unit 144 may use, as supervisor data, substrate measurement information, which is obtained by measuring the state of the substrate in advance, or with which the state of the substrate is known in advance, in an example of the supervised learning. As such a substrate, a substrate with a resist film of a specific resist pattern formed thereon may be used in an example.

Also, the learning model generation unit 144 may execute reinforcement learning and learn the learning model. The reinforcement learning is a method of giving an award to an action (output) executed on a current state (input) in a certain environment and generating such a learning model that allows the maximum award to be obtained. In an example in which the reinforcement learning is performed, the learning model generation unit 144 includes an evaluation value calculation unit 145 that calculates an evaluation value on the basis of the state variable SV and a learning unit 146 that performs learning of the learning model on the basis of the evaluation value. In an example, the evaluation value calculation unit 145 may give a larger award as the time required by the plating apparatus 1000 to perform the plating process on the substrate Wf is shorter. Also, in an example, the evaluation value calculation unit 145 may give a larger award as the profile of the plating film formed on the substrate Wf is more constant.

The substrate state measurement module 130 according to the embodiment described above is adapted such that the substrate Wf is arranged on the stage 132, the white confocal sensor 136 detects the surface of the substrate Wf while the substrate Wf is rotated, and the state of the substrate Wf is measured on the basis of the detection. It is thus possible to measure the state of the substrate Wf as a plating target and performs the plating process. Particularly, it is possible to suitably perform the plating process by detecting the contact area CA, the sealed area SA, and the plated area PA and measuring the state of the substrate.

### <Modification>

FIG. 11 is a longitudinal sectional view schematically illustrating a configuration of a substrate state measurement module according to a modification. Description of parts of a substrate state measurement module 130A according to the modification overlapping those in the substrate state measurement module 130 according to the aforementioned embodiment will be omitted. The substrate state measurement module 130A according to the modification includes a plurality of white confocal sensors 136. In an example, the substrate state measurement module 130A includes at least two of a first white confocal sensor 136a that detects the contact area CA as a detection target, a second white confocal sensor 136b that detects the sealed area SA as a detection target, and a third white confocal sensor 136c that detects the plated area PA as a detection target. In this manner, it is possible to detect the state of the substrate Wf by each white confocal sensor 136. Note that at least one of the first to third white confocal sensors 136a to 136c may be configured to be movable along the plate surface of the substrate Wf by the moving mechanism 138 similarly to the white confocal sensor 136 in the aforementioned embodiment. Particularly, the white confocal sensor 136c that detects the plated area PA as a detection target may include a plurality of sensors that detect different plated areas PA in the radial direction of the substrate Wf as illustrated in FIG. 11. Note that in the substrate state measurement module 130A according to the modification, the second and third white confocal sensors 136b and 136c correspond to examples of the white confocal sensor for detecting areas other than the contact area CA.

The present invention can also be described as the following aspects.

[Aspect 1] According to Aspect 1, proposed is a substrate state measurement device, the substrate state measurement device includes: a stage configured to support a substrate such that the stage is able to rotate the substrate, the substrate including a seed layer and a resist layer formed on the seed layer; and at least one white confocal sensor adapted to measure a plate surface of the substrate supported by the stage, and a state of a power supply member contact area is measured on the basis of detection performed by the white confocal sensor on the power supply member contact area, the power supply member contact area being an area on the substrate which comes into contact with a power supply member.

According to Aspect 1, the state of the power supply member contact area on the substrate as a plating target can be measured.

[Aspect 2] According to Aspect 2, proposed is a substrate state measurement device, the substrate state measurement device includes: a stage configured to support a substrate such that the stage is able to rotate the substrate, the substrate including a seed layer and a resist layer formed on the seed layer; and at least one white confocal sensor adapted to measure a plate surface of the substrate supported by the stage, and a state of a sealing member contact area is measured on the basis of detection performed by the white confocal sensor on the sealing member contact area, the sealing member contact area being an area on the substrate which comes into contact with a sealing member.

According to Aspect 2, it is possible to measure the state of the sealing member contact area on the substrate.

[Aspect 3] According to Aspect 3, proposed is a substrate state measurement device, and the substrate state measurement device includes: a stage configured to support a substrate such that the stage is able to rotate the substrate, the substrate including a seed layer and a resist layer formed on the seed layer; and at least one white confocal sensor adapted to measure a plate surface of the substrate supported by the stage, and a state of a plated area is measured on the basis of detection performed by the white confocal sensor on the plated area on the substrate.

According to Aspect 3, it is possible to measure the state of the plated area on the substrate.

[Aspect 4] According to Aspect 4, the detection performed by the white confocal sensor on the plated area on the substrate is performed on an area of not more than 25% of the plated area, in Aspect 3.

[Aspect 5] According to Aspect 5, an aperture ratio of the resist layer in the plated area is measured as a state of the plated area, in Aspect 3 or 4.

According to Aspect 5, it is possible to measure the aperture ratio in the plated area.

[Aspect 6] According to Aspect 6, a storage unit that stores a learning model constructed through machine learning is included, and learning of the learning model is performed by inputting detection information obtained by the white confocal sensor to the learning model, and the aperture ratio of the resist layer in the plated area is measured by using the learning model, in Aspect 5.

According to Aspect 6, it is possible to suitably measure the aperture ratio in the plated area by using the learning model.

[Aspect 7] According to Aspect 7, a moving mechanism configured to move the white confocal sensor along the plate surface of the substrate is included, in Aspects 1 to 6.

According to Aspect 7, it is possible to change the detection position of the white confocal sensor by the moving mechanism.

[Aspect 8] According to Aspect 8, the at least one white confocal sensor includes a first white confocal sensor adapted to detect the power supply member contact area and a second white confocal sensor adapted to detect an area other than the power supply member contact area on the substrate, in Aspects 1 to 7.

[Aspect 9] According to Aspect 9, proposed is a plating apparatus including: the substrate state measurement device according to any of Aspects 1 to 8; a substrate holder including the power supply member and adapted to hold the substrate; and a plating tank adapted to accommodate a plating solution and perform plating by applying a voltage between the substrate and an anode in a state where the substrate held by the substrate holder and the anode are immersed in the plating solution.

[Aspect 10] According to Aspect 10, proposed is a substrate state measurement method, and the substrate state measurement method includes: arranging a substrate on a stage, the substrate including a seed layer and a resist layer formed on the seed layer; detecting a power supply member contact area by a white confocal sensor while rotating the substrate arranged on the stage, the power supply member contact area being an area on the substrate which comes into contact with a power supply member; and measuring a state of the power supply member contact area on the basis of detection performed by the white confocal sensor.

[Aspect 11] According to Aspect 11, proposed is a substrate state measurement method, and the substrate state measurement method includes: arranging a substrate on a stage, the substrate including a seed layer and a resist layer formed on the seed layer; detecting a sealing member contact area by a white confocal sensor while rotating the substrate arranged on the stage, the sealing member contact area being an area on the substrate which comes into contact with a sealing member; and measuring a state of the sealing member contact area on the basis of detection performed by the white confocal sensor.

[Aspect 12] According to Aspect 12, proposed is a substrate state measurement method, and the substrate state measurement method includes: arranging a substrate on a stage, the substrate including a seed layer and a resist layer formed on the seed layer; detecting a plated area on the substrate by a white confocal sensor while rotating the substrate arranged on the stage; and measuring a state of the plated area on the basis of detection performed by the white confocal sensor.

The embodiments of the present invention have been described above, and the above embodiments of the present invention are described to facilitate understanding of the present invention and are not intended to limit the present invention. Needless to say, the present invention may be changed or modified without departing from the spirit, and the present invention includes equivalents to the invention. Also, in a range in which at least some of the above-described problems can be solved or a range in which at least some of effects are exhibited, any arbitrary combination of the embodiment and the modification is possible, and arbitrary combination or omission of respective constituent components described in claims and description is possible.

### REFERENCE SIGNS LIST

Wf substrate
RL resist layer
SL seed layer
CA contact area
PA plated area
SA sealed area
100 load port
110 transfer robot
120 aligner
130, 130A substrate state measurement module
132 stage
134 rotation mechanism
136 white confocal sensor
138 moving mechanism
150 storage unit
200 pre-wet module
300 pre-soak module
400 plating module
410 plating tank
430 anode
440 substrate holder
441 sealing member
800 control module
1000 plating apparatus

1. A substrate state measurement device comprising:
a stage configured to support a substrate such that the stage is able to rotate the substrate, the substrate including a seed layer and a resist layer formed on the seed layer; and
at least one white confocal sensor adapted to measure a plate surface of the substrate supported by the stage,
wherein a state of a power supply member contact area is measured on the basis of detection performed by the white confocal sensor on the power supply member contact area, the power supply member contact area being an area on the substrate which comes into contact with a power supply member.

2. A substrate state measurement device comprising:
a stage configured to support a substrate such that the stage is able to rotate the substrate, the substrate including a seed layer and a resist layer formed on the seed layer; and
at least one white confocal sensor adapted to measure a plate surface of the substrate supported by the stage,
wherein a state of a sealing member contact area is measured on the basis of detection performed by the white confocal sensor on the sealing member contact area, the sealing member contact area being an area on the substrate which comes into contact with a sealing member.

3. A substrate state measurement device comprising:
a stage configured to support a substrate such that the stage is able to rotate the substrate, the substrate including a seed layer and a resist layer formed on the seed layer; and
at least one white confocal sensor adapted to measure a plate surface of the substrate supported by the stage,
wherein a state of a plated area is measured on the basis of detection performed by the white confocal sensor on the plated area on the substrate.

4. The substrate state measurement device according to claim 3, wherein the detection performed by the white confocal sensor on the plated area on the substrate is performed on an area of not more than 25% of the plated area.

5. The substrate state measurement device according to claim 3 or 4, wherein an aperture ratio of the resist layer in the plated area is measured as a state of the plated area.

6. The substrate state measurement device according to claim 5, comprising:
a storage unit that stores a learning model constructed through machine learning,
wherein learning of the learning model is performed by inputting detection information obtained by the white confocal sensor to the learning model, and the aperture ratio of the resist layer in the plated area is measured by using the learning model.

7. The substrate state measurement device according to any one of claims 1 to 3, comprising:
a sensor moving mechanism configured to move the white confocal sensor along the plate surface of the substrate.

8. The substrate state measurement device according to any one of claims 1 to 3, wherein the at least one white confocal sensor includes a first white confocal sensor adapted to detect the power supply member contact area and a second white confocal sensor adapted to detect an area other than the power supply member contact area on the substrate.

9. A plating apparatus comprising:
the substrate state measurement device according to any one of claims 1 to 3;
a substrate holder including the power supply member and adapted to hold the substrate; and
a plating tank adapted to accommodate a plating solution and perform plating by applying a voltage between the substrate and an anode in a state where the substrate held by the substrate holder and the anode are immersed in the plating solution.

10. A substrate state measurement method comprising:
arranging a substrate on a stage, the substrate including a seed layer and a resist layer formed on the seed layer;
detecting a power supply member contact area by a white confocal sensor while rotating the substrate arranged on the stage, the power supply member contact area being an area on the substrate which comes into contact with a power supply member; and
measuring a state of the power supply member contact area on the basis of detection performed by the white confocal sensor.

11. A substrate state measurement method comprising:
arranging a substrate on a stage, the substrate including a seed layer and a resist layer formed on the seed layer;
detecting a sealing member contact area by a white confocal sensor while rotating the substrate arranged on the stage, the sealing member contact area being an area on the substrate which comes into contact with a sealing member; and
measuring a state of the sealing member contact area on the basis of detection performed by the white confocal sensor.

12. A substrate state measurement method comprising:
arranging a substrate on a stage, the substrate including a seed layer and a resist layer formed on the seed layer;
detecting a plated area on the substrate by a white confocal sensor while rotating the substrate arranged on the stage; and
measuring a state of the plated area on the basis of detection performed by the white confocal sensor.
